(19) United States
(12) Patent Application Publication
(10) Pub. No.: US 2023/0145732 A1
(43) Pub. Date: May 11, 2023

(54) Trench Fabrication Method

(71) Applicant: HANGZHOU FULLSEMI SEMICONDUCTOR CO., LTD., HANGZHOU (CN)

(72) Inventor: Peng Lei, HANGZHOU (CN)

(21) Appl. No.: 17/952,754

(22) Filed: Sep. 26, 2022

(30) Foreign Application Priority Data
Nov. 10, 2021 (CN) 202111326597.5

(51) Int. Cl. H01L 21/311; H01L 21/02

(52) U.S. Cl. CPC H01L 21/31111; H01L 21/0214; H01L 21/02164; H01L 21/0217; H01L 21/31144

(57) ABSTRACT

Provided is a trench fabrication method including: forming a first dielectric layer on a semiconductor substrate; patterning/etching the first dielectric layer to form a first trench; forming a sacrificial layer for filling the first trench; forming a second dielectric layer for covering the first dielectric layer and the sacrificial layer; etching the second dielectric layer to form a second trench for exposing the sacrificial layer; and removing the sacrificial layer to form a trench whereby the first trench and the second trench are aligned and connected with each other. The trench fabrication method involves effecting deposition step by step and etching the dielectric layers step by step, so as to fabricate a trench with a high aspect ratio, render the fabrication process simple and easy, enhance process precision, reduce product defect risks, and increase product yield.

### FIELD OF DISCLOSURE

The present disclosure relates to semiconductor manufacturing and, more particularly, to a trench fabrication method.

### BACKGROUND

Etching is not only a very important step in a semiconductor manufacturing process but also a major process of patterning associated with photolithography. Strictly speaking, etching includes photolithography and corrosion, as it entails subjecting a photoresist to photolithographic exposure by photolithography and then removing unwanted parts of the photoresist through corrosion.

Chip area reduction is a collective goal in ongoing chip development to meet the increasingly high requirements for device performance. Moreover, trenches are formed on substrates to raise performance metrics of chips. However, the ever-decreasing chip areas has lead to the ever-decreasing sizes of the trenches fabricated, and in consequence trenches with a high aspect ratio have to be etched in the course of fabrication of semiconductor chips. Etching trenches with a high aspect ratio poses a challenge to the processing capability of machines, renders processing precision control difficult, and causes an offset between the bottom of each trench and a pattern defined with masks in terms of the shape and size of the bottom of the trench to thereby result in defects or open circuits. As a result, not only is it difficult to increase the product yield of existing trench fabrication processes, but the existing trench fabrication processes are also disadvantaged by high product defect risks.

Therefore, it is necessary to provide a trench fabrication method.

### SUMMARY OF INVENTION

In view of the aforesaid drawbacks, the present disclosure provides a trench fabrication method to overcome drawbacks of conventional processes of fabricating trenches with a high aspect ratio, namely great process difficulty, low processing precision, and low product yield.

In order to achieve the above and other objectives, the present disclosure provides a trench fabrication method, comprising the steps of:

providing a semiconductor substrate;

forming a first dielectric layer on the semiconductor substrate;

forming a patterned first photoresist layer on the first dielectric layer;

etching the first dielectric layer to form a first trench penetrating the first dielectric layer, with the first trench being of a first width;

removing the first photoresist layer to expose the first dielectric layer;

forming a sacrificial layer, with the sacrificial layer covering the first dielectric layer and filling the first trench;

removing a portion of the sacrificial layer to expose the first dielectric layer;

forming a second dielectric layer, with the second dielectric layer covering the first dielectric layer and the sacrificial layer;

forming a patterned second photoresist layer on the second dielectric layer;

etching the second dielectric layer to form a second trench penetrating the second dielectric layer, with the second trench being of a second width, thereby exposing the sacrificial layer from the second trench; and

removing the second photoresist layer and the sacrificial layer to form a trench for exposing the semiconductor substrate.

Preferably, the second width of the second trench is greater than the first width of the first trench.

Preferably, the first trench and the second trench are each axisymmetric, and axes of the first and second trenches are colinear and vertical.

Preferably, between the step of removing the second photoresist layer and the step of removing the sacrificial layer, the step of forming the sacrificial layer and dielectric layers is recurringly performed M times, where M denotes a positive integer greater than or equal to 1.

Preferably, the first dielectric layer and the second dielectric layer are made of the same material.

Preferably, an aspect ratio of the first trench ranges from 1:1 to 100:1, and an aspect ratio of the second trench ranges from 1:1 to 100:1.

Preferably, the first trench is a deep-hole trench or a deep-groove trench, and the second trench is a deep-hole trench or a deep-groove trench.

Preferably, a cross section of the first trench has a shape which is one of rectangular, inverted-trapezoid, V-shaped and U-shaped, and a cross section of the second trench has a shape which is one of rectangular, inverted-trapezoid, V-shaped and U-shaped.

Preferably, the first dielectric layer is a silicon oxide layer, silicon nitride layer or silicon oxynitride layer, and the second dielectric layer is a silicon oxide layer, silicon nitride layer or silicon oxynitride layer.

Preferably, the sacrificial layer is a back side anti-reflection-coated (BARC) layer.

As mentioned above, a trench fabrication method of the present disclosure entails forming a first dielectric layer on a semiconductor substrate, etching the first dielectric layer to form a first trench, forming a sacrificial layer for filling the first trench, forming a second dielectric layer, etching the second dielectric layer to form a second trench for exposing the sacrificial layer, removing the sacrificial layer to form a trench whereby the first trench and the second trench are in communication with each other. Therefore, the trench fabrication method involves effecting deposition step by step and etching the dielectric layers step by step, so as to fabricate a trench with a high aspect ratio, render the fabrication process simple and easy, enhance process precision, reduce product defect risks effectively, and increase product yield.

### DESCRIPTION OF DRAWINGS

FIG. 1 illustrates the process flow chart for fabricating a trench according to an embodiment of the present disclosure.

FIG. 2 is a schematic cross sectional view of a semiconductor substrate after a patterned first photoresist layer has been formed according to an embodiment of the present disclosure.

FIG. 3 is a schematic cross sectional view of the semiconductor substrate after a first trench has been etched according to an embodiment of the present disclosure.

FIG. 4 is a schematic cross sectional view of the semiconductor substrate after a sacrificial layer has been formed according to an embodiment of the present disclosure.

FIG. 5 is a schematic cross sectional view of the semiconductor substrate after a portion of the sacrificial layer has been removed according to an embodiment of the present disclosure.

FIG. 6 is a schematic cross sectional view of the semiconductor substrate after a patterned second photoresist layer has been formed according to an embodiment of the present disclosure.

FIG. 7 is a schematic cross sectional view of the semiconductor substrate after a second trench has been etched according to an embodiment of the present disclosure.

FIG. 8 is a schematic cross sectional view of the semiconductor substrate after the second photoresist layer and the sacrificial layer have been removed according to an embodiment of the present disclosure.

### DETAILED DESCRIPTION OF PREFERRED EMBODIMENTS

The present disclosure is hereunder illustrated by specific embodiments to enable persons skilled in the art to easily gain insight into the advantages and effects of the present disclosure. The present disclosure can be implemented or applied in accordance with any other variant embodiments. Various modifications and changes may be made to the details in the specification from different perspectives and for different applications without departing from the spirit of the present disclosure.

For the sake of illustration, cross-sectional views of device structures described in the embodiments of the present disclosure may be enlarged partially rather than drawn to scale, and the schematic views are illustrative rather than restrictive of the scope of the claims of the present disclosure. Furthermore, the device structures are three-dimensional (i.e., having length, breadth and depth) in the course of their production.

For the sake of illustration, terms about a spatial relation, such as “under,” “below,” “lower than,” “beneath,” “above” and “on,” are used hereunder to describe the position of a component or feature relative to another component or feature in the accompanying drawings. In addition to directions depicted in the accompanying drawings, the spatial relation terms are intended to indicate any other directions in which the devices are used or operate. Moreover, when a layer is referred to with the expression “between two layers,” it may exist as the only layer between the two layers or exist in the presence of one or more intervening layers. The preposition “between” used herein shall be interpreted as an inclusive range, i.e., a range inclusive of the endpoints.

In the descriptions below, the expression “a first feature on a second feature” may mean that the first and second features are in direct contact in an embodiment, or may mean that in another embodiment a further feature is formed between the first and second features to prevent direct contact therebetween.

The accompanying drawings depict schematically essential features disclosed in the present disclosure and show components relevant to the present disclosure not according to the number, shape and size of the components actually implemented. When actually implemented, the shape, number and proportions of the components are subject to changes, and the arrangement of the components can be even more complicated.

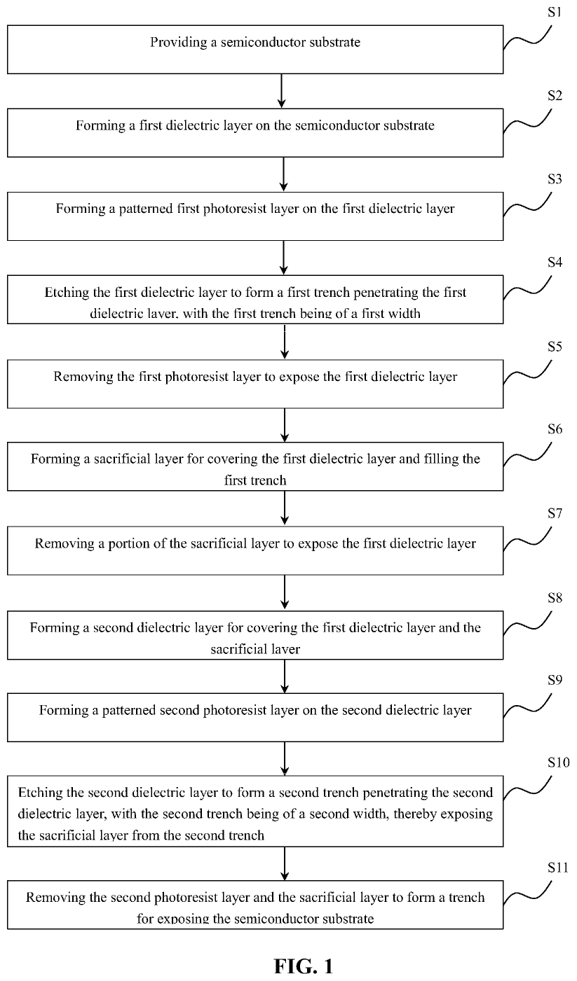

Referring to flow chart in FIG. 1, this embodiment provides a trench fabrication method, comprising the steps of:

S1: provide a semiconductor substrate;

S2: form a first dielectric layer on the semiconductor substrate;

S3: form a patterned first photoresist layer on the first dielectric layer;

S4: etch the first dielectric layer to form a first trench penetrating the first dielectric layer, with the first trench being of a first width;

S5: remove the first photoresist layer to expose the first dielectric layer;

S6: form a sacrificial layer, with the sacrificial layer covering the first dielectric layer and filling the first trench;

S7: remove a portion of the sacrificial layer to expose the first dielectric layer;

S8: form a second dielectric layer, with the second dielectric layer covering the first dielectric layer and the sacrificial layer;

S9: form a patterned second photoresist layer on the second dielectric layer;

S10: etch the second dielectric layer to form a second trench penetrating the second dielectric layer, with the second trench being of a second width, thereby exposing the sacrificial layer from the second trench; and

S11: remove the second photoresist layer and the sacrificial layer to form a trench for exposing the semiconductor substrate.

This embodiment entails forming a first dielectric layer on a semiconductor substrate, etching the first dielectric layer to form a first trench, forming a sacrificial layer for filling the first trench, forming a second dielectric layer, etching the second dielectric layer to form a second trench for exposing the sacrificial layer, removing the sacrificial layer to form a trench whereby the first trench and the second trench are in communication with each other. Therefore, the trench fabrication method of the present disclosure involves effecting deposition step by step and etching the dielectric layers step by step, so as to fabricate a trench with a high aspect ratio, render the fabrication process simple and easy, enhance process precision, reduce product defect risks effectively, and increase product yield.

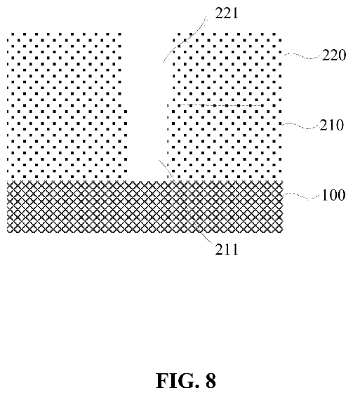

A fabrication process of the trench in this embodiment is illustrated by FIG. 2˜FIG. 8 and described below.

Step S1 involves providing a semiconductor substrate 100.

Referring to FIG. 2, in this embodiment the semiconductor substrate 100 is a silicon substrate, but the present disclosure is not limited thereto. In a variant embodiment, the semiconductor substrate 100 is a silicon-on-insulator (SOI) substrate, silicon-germanium (SiGe) substrate, silicon carbide substrate, germanium-on-insulator (GeOI) substrate, or III-V compound substrate. The semiconductor substrate 100 comprises therein a doped region. The embodiment and variant embodiment are not restrictive of the present disclosure in terms of the specific structure of the semiconductor substrate 100 and the material which the semiconductor substrate 100 is made of.

Step S2 involves forming a first dielectric layer 210 on the semiconductor substrate 100.

For instance, the first dielectric layer 210 is a silicon oxide layer, silicon nitride layer or silicon oxynitride layer. In this embodiment, the first dielectric layer 210 is a silicon oxide layer, but the present disclosure is not limited thereto. In a variant embodiment, the first dielectric layer 210 is any other insulating medium layer as needed. The silicon oxide layer is formed by CVD deposition, but its specific technique and the thickness of the first dielectric layer 210 thus deposited are subject to changes as needed.

Step S3 involves forming a patterned first photoresist layer 310 on the first dielectric layer 210.

Referring to FIG. 2, the step of forming the first photoresist layer 310 on the first dielectric layer 210 includes the sub-steps of coating, exposure, development and heating, which, however, are not restrictive of the method of forming the first photoresist layer 310 of the present disclosure.

Step S4 involves etching the first dielectric layer 210 to form a first trench 211 penetrating the first dielectric layer 210, with the first trench 211 being of a first width.

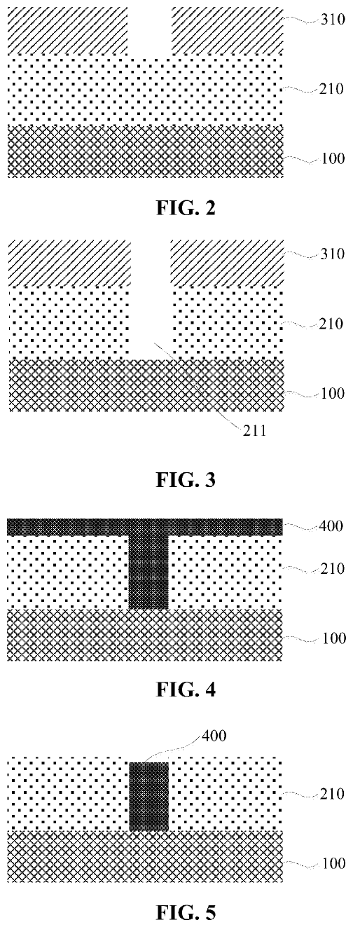

Referring to FIG. 3, with the patterned first photoresist layer 310 serving as a mask, an etching process is carried out to form the first trench 211 in the first dielectric layer 210, such that the semiconductor substrate 100 is exposed from the first trench 211. The width and depth of the first trench 211 are subject to changes as needed. Preferably, an aspect ratio of the first trench 211 ranges from 1:1 to 100:1 and thus is, for example, 1:1, 10:1, 50:1, or 100:1 and subject to changes as needed.

For instance, the first trench 211 is a deep-hole trench or a deep-groove trench. The shape of the first trench 211 is subject to changes as needed. For instance, a cross section of the first trench 211 is rectangular, inverted-trapezoid, V-shaped or U-shaped. In this embodiment, the cross section of the first trench 211 is rectangular, but the present disclosure is not limited thereto.

Step S5 involves removing the first photoresist layer 310 to expose the first dielectric layer 210.

Step S6 involves forming a sacrificial layer 400, with the sacrificial layer 400 covering the first dielectric layer 210 and filling the first trench 211.

Referring to FIG. 4, the sacrificial layer 400 covers the first dielectric layer 210. The sacrificial layer 400 is a BARC layer, but the present disclosure is not limited thereto. The sacrificial layer 400 is made of a material which has a high etching selectivity ratio relative to the first dielectric layer 210 to thereby avoid causing damage to the first dielectric layer 210 in the course of removing the sacrificial layer 400. The selection of the material which the sacrificial layer 400 is to be made of is contingent on the first dielectric layer 210; this, however, is not restrictive of the present disclosure.

Step S7 involves removing a portion of the sacrificial layer 400 to expose the first dielectric layer 210.

Referring to FIG. 5, an etch-back process is carried out to etch back the BARC layer and thereby expose the first dielectric layer 210, so as to facilitate subsequent processes. Thus, when the first-instance deposition and etching steps are completed, the sacrificial layer 400, which is of a predetermined shape and is dedicated to transitional filling, is formed in the first dielectric layer 210.

Step S8 involves forming a second dielectric layer 220, with the second dielectric layer 220 covering the first dielectric layer 210 and the sacrificial layer 400.

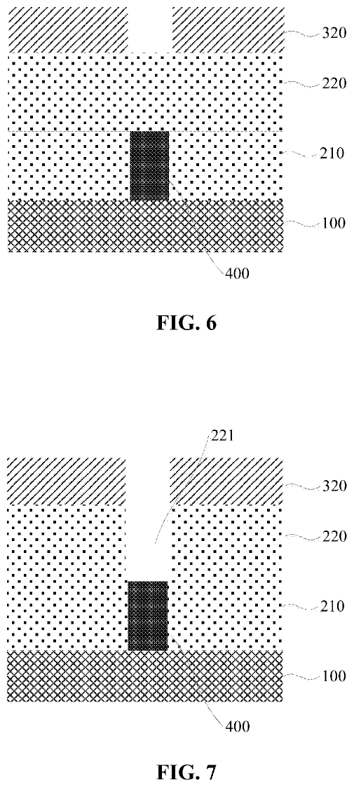

Referring to FIG. 6, the second dielectric layer 220 is made of silicon oxide, silicon nitride or silicon oxynitride. In this embodiment, the second dielectric layer 220 and the first dielectric layer 210 are made of the same material, that is, silicon oxide layer, but the present disclosure is not limited thereto. In a variant embodiment, the second dielectric layer 220 is any other insulating medium layer. The silicon oxide layer is formed by CVD deposition. The technique of carrying out CVD deposition and the thickness of the second dielectric layer 220 deposited are subject to changes as needed.

Step S9 involves forming a patterned second photoresist layer 320 on the second dielectric layer 220.

Referring to FIG. 6, the step of forming the second photoresist layer 320 on the second dielectric layer 220 includes the sub-steps of coating, exposure, development and heating, which, however, are not restrictive of the method of forming the second photoresist layer 320 of the present disclosure. The second photoresist layer 320 and the first photoresist layer 310 are made of the same material or different materials.

Step S10 involves etching the second dielectric layer 220 to form a second trench 221 penetrating the second dielectric layer 220, with the second trench 221 being of a second width, thereby exposing the sacrificial layer 400 from the second trench 221.

Referring to FIG. 7, with the patterned second photoresist layer 320 serving as a mask, an etching process is carried out to form the second trench 221 in the second dielectric layer 220, such that the sacrificial layer 400 is exposed from the second trench 221. The width and depth of the second trench 221 are subject to changes as needed. Preferably, an aspect ratio of the second trench 221 ranges from 1:1 to 100:1 and thus is, for example, 1:1, 10:1, 50:1, or 100:1 and subject to changes as needed.

For instance, the second trench 221 is a deep-hole trench or a deep-groove trench. The shape of the second trench 221 is subject to changes as needed. For example, the cross section of the second trench 221 is rectangular, inverted-trapezoid, V-shaped or U-shaped. In this embodiment, the cross section of the second trench 221 is rectangular, but the present disclosure is not limited thereto.

For instance, preferably, the second width of the second trench 221 is greater than the first width of the first trench 211, and thus the second trench 221 is conducive to effective removal of the sacrificial layer 400 from the first trench 211, so as for the second trench 221 and the first trench 211 to be in communication with each other.

For instance, preferably, not only are the first trench 211 and the second trench 221 each axisymmetric, but the axis of the first trench 211 and the axis of the second trench 221 are also colinear and vertical, so as to facilitate the removal of the sacrificial layer 400 from the first trench 211 and the formation of the axisymmetric first and second trenches 211, 221, render subsequent material filling easy, and enhance product quality.

Step S11 involves removing the second photoresist layer 320 and the sacrificial layer 400 to form a trench for exposing the semiconductor substrate 100.

The removal of the sacrificial layer 400 for the sake of allowing the first trench 211 and the second trench 221 to be in communication with each other is followed by effecting deposition step by step and etching the dielectric layers step by step, so as to fabricate a trench with a high aspect ratio, render the fabrication process simple and easy, enhance process precision, reduce product defect risks effectively, and increase product yield.

For instance, between the step of removing the second photoresist layer 320 and the step of removing the sacrificial layer 400, the step of forming the sacrificial layer and dielectric layers is recurringly performed M times, where M denotes a positive integer greater than or equal to 1.

Steps S6˜S10 are performed again after the step of removing the second photoresist layer 320 but before the step of removing the sacrificial layer 400 to ensure that the trench of a target depth can be eventually attained. M is 1, 2 or 3 as appropriate. For conciseness, related details are omitted.

In conclusion, a trench fabrication method of the present disclosure entails forming a first dielectric layer on a semiconductor substrate, etching the first dielectric layer to form a first trench, forming a sacrificial layer for filling the first trench, forming a second dielectric layer, etching the second dielectric layer to form a second trench for exposing the sacrificial layer, removing the sacrificial layer, and forming a trench whereby the first trench and the second trench are in communication with each other. Thus, the present disclosure is effective in effecting deposition step by step and etching the dielectric layers step by step, so as to fabricate a trench with a high aspect ratio, render the fabrication process simple and easy, enhance process precision, reduce product defect risks, and increase product yield. Therefore, the present disclosure effectively overcomes the drawbacks of the prior art and thereby has high industrial applicability.

The above embodiments are illustrative of the principles and benefits of the present disclosure rather than restrictive of the scope of the present disclosure. Persons skilled in the art can make modifications and changes to the embodiments without departing from the spirit and scope of the present disclosure. Therefore, all equivalent modifications and changes made by persons skilled in the art without departing from the spirit and technical concepts disclosed in the present disclosure shall still be deemed falling within the scope of the claims of the present disclosure.

What is claimed is:

1. A trench fabrication method, comprising steps of:
providing a semiconductor substrate;
forming a first dielectric layer on the semiconductor substrate;
forming a first photoresist layer and patterning the first photoresist layer on the first dielectric layer;
etching the first dielectric layer using the patterned first photoresist layer as a mask to form a first trench penetrating the first dielectric layer, wherein the first trench comprises a first width;
removing the first photoresist layer to expose the first dielectric layer;
forming a sacrificial layer on the first dielectric layer, wherein the sacrificial layer fills in the first trench;
removing a portion of the sacrificial layer to expose the first dielectric layer outside the first trench and a top surface of the sacrificial layer in the first trench;
forming a second dielectric layer on the first dielectric layer and the top surface of the sacrificial layer in the first trench;
forming a second photoresist layer and patterning the second photoresist layer on the second dielectric layer;
etching the second dielectric layer using the patterned second photoresist layer as a mask to form a second trench penetrating the second dielectric layer, wherein the second trench align with the sacrificial layer in first trench, wherein the second trench comprises a second width, and wherein the top surface of the sacrificial layer is exposed from the second trench; and
removing the second photoresist layer and the sacrificial layer to form a trench for exposing the semiconductor substrate.

2. The trench fabrication method of claim 1, wherein the second width of the second trench is greater than the first width of the first trench.

3. The trench fabrication method of claim 1, wherein the first trench and the second trench are each axisymmetric, and wherein axes of the first and second trenches are colinear and perpendicular to a top surface of the substrate.

4. The trench fabrication method of claim 1, wherein, between the step of removing the second photoresist layer and the step of removing the sacrificial layer, the step of forming the sacrificial layer and dielectric layer is recurringly performed M times, where M denotes a positive integer greater than or equal to 1.

5. The trench fabrication method of claim 1, wherein the first dielectric layer and the second dielectric layer are made of the same material.

6. The trench fabrication method of claim 1, wherein an aspect ratio of the first trench ranges from 1:1 to 100:1, and an aspect ratio of the second trench ranges from 1:1 to 100:1.

7. The trench fabrication method of claim 1, wherein the first trench is a deep-hole trench or a deep-groove trench, and wherein the second trench is a deep-hole trench or a deep-groove trench.

8. The trench fabrication method of claim 1, wherein a cross sectional shape of the first trench comprises one of rectangular, inverted-trapezoid, V-shaped and U-shaped, and wherein a cross sectional shape of the second trench comprises one of rectangular, inverted-trapezoid, V-shaped and U-shaped.

9. The trench fabrication method of claim 1, wherein the first dielectric layer is one of a silicon oxide layer, a silicon nitride layer and a silicon oxynitride layer, and wherein the second dielectric layer is one of a silicon oxide layer, a silicon nitride layer and a silicon oxynitride layer.

10. The trench fabrication method of claim 1, wherein the sacrificial layer is a BARC layer.
